(19) United States
(12) Patent Application Publication
(10) Pub. No.: US 2023/0298864 A1
(43) Pub. Date: Sep. 21, 2023

(54) UPPER ELECTRODE AND PLASMA PROCESSING APPARATUS

(71) Applicant: Tokyo Electron Limited, Tokyo (JP)

(72) Inventors: Shinya YAMANAKA, Miyagi (JP); Takashi KITAZAWA, Miyagi (JP)

(21) Appl. No.: 18/120,050

(22) Filed: Mar. 10, 2023

(30) Foreign Application Priority Data
Mar. 18, 2022 (JP) 2022-043961

(51) Int. Cl. H01J 37/32

(52) U.S. Cl. CPC H01J 37/32541; H01J 37/32568; H01J 37/32091

(57) ABSTRACT

An upper electrode disclosed forms a shower head in a capacitively-coupled plasma processing apparatus. The upper electrode includes a first member, a second member, and a third member. The first member is formed of a conductor. The first member provides a first gas hole. The first gas hole penetrates the first member. The second member is formed of a conductor. The second member is provided on the first member. The second member provides a second gas hole. The third member is formed of a dielectric. The third member is provided between the first member and the second member. The third member defines the gas diffusion chamber. The first gas hole and the second gas hole are connected to the gas diffusion chamber.

### CROSS-REFERENCE TO RELATED APPLICATION

This application is based upon and claims the benefit of priority from Japanese Patent Application No. 2022-043961, filed on Mar. 18, 2022, the entire contents of which are incorporated herein by reference.

### TECHNICAL FIELD

The present disclosure relates to an upper electrode and a plasma processing apparatus.

### BACKGROUND

In plasma processing on a substrate, a plasma processing apparatus is used. One type of plasma processing apparatus is a capacitively-coupled plasma processing apparatus and includes a plasma processing chamber, a substrate support, and an upper electrode. The upper electrode is provided above the substrate support and forms a shower head. A gas diffusion chamber into which a processing gas is introduced from a gas introduction port is defined inside the upper electrode.

### PRIOR ART DOCUMENTS

### Patent Documents

Patent Document 1: Japanese Patent Application Publication No. 2001-298015

### SUMMARY

The present disclosure provides a technique for suppressing an abnormal discharge in an upper electrode.

In one exemplary embodiment, an upper electrode is provided. The upper electrode forms a shower head in a capacitively-coupled plasma processing apparatus. The upper electrode includes a first member, a second member, and a third member. The first member is formed of a conductor. The first member provides a plurality of first gas holes. The plurality of first gas holes penetrates the first member. The second member is formed of a conductor. The second member is provided on the first member. The second member provides one or more second gas holes. The third member is formed of a dielectric. The third member is provided between the first member and the second member. The third member defines a gas diffusion chamber. In the gas diffusion chamber, the plurality of first gas holes and the one or more second gas holes are connected.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view for explaining an example of a configuration of a capacitively-coupled plasma processing apparatus.

FIG. 2 is a cross-sectional view of an upper electrode according to one exemplary embodiment.

FIG. 3 is a perspective view of a second member according to one exemplary embodiment.

FIG. 4 is a cross-sectional view illustrating a part of the upper electrode according to one exemplary embodiment.

FIG. 5 is a cross-sectional view illustrating a part of an upper electrode according to another exemplary embodiment.

FIG. 6 is a cross-sectional view illustrating a part of an upper electrode according to yet another exemplary embodiment.

FIG. 7 is a cross-sectional view illustrating a part of an upper electrode according to still another exemplary embodiment.

FIG. 8 is a cross-sectional view illustrating a part of an upper electrode according to yet another exemplary embodiment.

FIG. 9 is a cross-sectional view illustrating a part of an upper electrode according to still another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In one exemplary embodiment, an upper electrode is provided. The upper electrode forms a shower head in a capacitively-coupled plasma processing apparatus. The upper electrode includes a first member, a second member, and a third member. The first member is formed of a conductor. The first member provides a plurality of first gas holes. The plurality of first gas holes penetrates the first member. The second member is formed of a conductor. The second member is provided on the first member. The second member provides one or more second gas holes. The third member is formed of a dielectric. The third member is provided between the first member and the second member. The third member defines a gas diffusion chamber. In the gas diffusion chamber, the plurality of first gas holes and the one or more second gas holes are connected.

In the embodiment, the gas diffusion chamber is defined by the third member formed of a dielectric. Therefore, even when electrons or positive ions enter the gas diffusion chamber from each of the plurality of first gas holes and collide with the third member that defines the gas diffusion chamber, the amount of secondary electrons emitted from the third member is small. As a result, an abnormal discharge in the upper electrode is suppressed.

In one exemplary embodiment, the upper electrode may further include at least one of a first sealing member and a second sealing member. The first sealing member is held between the first member and the third member. The second sealing member is held between the second member and the third member. The first sealing member suppresses formation of the flow of a processing gas toward a gap between the first member and the third member. The second sealing member suppresses formation of the flow of a processing gas toward a gap between the second member and the third member. At least one selected from the group of the first sealing member and the second sealing member stabilizes the flow of the processing gas formed in the gas diffusion chamber.

In one exemplary embodiment, the third member may include a sidewall and a ceiling portion. The sidewall extends in a peripheral direction to surround the gas diffusion chamber. The ceiling portion extends on the gas diffusion chamber. The second sealing member may be held between the sidewall of the third member and the second member. Alternatively, the second sealing member may be held between the ceiling portion of the third member and the second member. The second sealing member is held between the second member and the third member, thereby exerting a reaction force with respect to the third member. The relative position of the third member with respect to the first member is fixed by the reaction force. Therefore, the friction between the third member and the first member is suppressed. As a result, generation of particles due to the friction between the third member and the first member is suppressed.

In one exemplary embodiment, the ceiling portion may be disposed to face an open end of each of the plurality of first gas holes on the side of the gas diffusion chamber. Since the open end of each of the plurality of first gas holes faces the ceiling portion, most of the electrons or positive ions entering the gas diffusion chamber from each of the plurality of first gas holes tend to collide with the ceiling portion. The secondary electrons are less likely to be emitted from the ceiling portion. Therefore, according to the embodiment, the abnormal discharge in the upper electrode is further suppressed.

In one exemplary embodiment, the third member may include a bottom portion. The bottom portion may be disposed below the gas diffusion chamber.

In one exemplary embodiment, the bottom portion may provide a plurality of third gas holes. The plurality of third gas holes may be aligned with the plurality of first gas holes, respectively. The electrons or positive ions entering the plurality of first gas holes may collide with the wall surface that defines the plurality of third gas holes before reaching the gas diffusion chamber. The wall surface that defines the plurality of third gas holes is less likely to emit the secondary electrons. Therefore, according to the embodiment, the abnormal discharge in the upper electrode is further suppressed.

In one exemplary embodiment, the second sealing member may be held between the second member and the bottom portion. By being held between the second member and the bottom portion, the second sealing member exerts a reaction force with respect to the third member. The relative position of the third member with respect to the first member is fixed by the reaction force. Therefore, the friction between the third member and the first member is suppressed. As a result, generation of particles due to the friction between the third member and the first member is suppressed.

In one exemplary embodiment, the first sealing member may be held between the first member and the bottom portion. In the embodiment, particles that may be generated by the friction between the third member and the first member are suppressed from entering the plurality of first gas holes.

In one exemplary embodiment, at least one selected from the group of the first sealing member and the second sealing member may separate a boundary between the first member and the second member from the gas diffusion chamber. In the embodiment, the boundary where an abnormal discharge is easily generated is separated from the gas diffusion chamber by at least one of the first sealing member and the second sealing member. Therefore, the abnormal discharge in the upper electrode is further suppressed.

In one exemplary embodiment, at least one selected from the group of the first sealing member and the second sealing member may separate the boundary between the first member and the second member from the plurality of third gas holes. At least one selected from the group of the first sealing member or the second sealing member suppresses particles that may be generated by the friction between the third member and the second member from entering the plurality of third gas holes.

In one exemplary embodiment, the third member may separate the boundary between the first member and the second member from the gas diffusion chamber. In the embodiment, a boundary B where an abnormal discharge is easily generated is separated from the gas diffusion chamber by the third member. Therefore, the abnormal discharge in the upper electrode is further suppressed.

In one exemplary embodiment, the third member may have a contact portion. The contact portion may be in contact with the first member. The contact portion may be formed of a low friction member. The low friction member may have a lower friction coefficient than that of a portion other than the contact portion of the third member. The first member is in contact with the contact portion. Therefore, frictional resistance between the first member and the third member is reduced. As a result, generation of particles due to the friction between the first member and the third member is suppressed.

In one exemplary embodiment, the dielectric may be a porous body.

In one exemplary embodiment, the first sealing member may be an O-ring. The first sealing member may be a gasket. The second sealing member may be the O-ring. The second sealing member may be the gasket.

In still another exemplary embodiment, a plasma processing apparatus includes a plasma processing chamber, a substrate support, and an upper electrode. The plasma processing chamber provides a processing space therein. The substrate support is provided in the plasma processing chamber. The upper electrode is an upper electrode of any one of the various exemplary embodiments described above, and is provided above the substrate support.

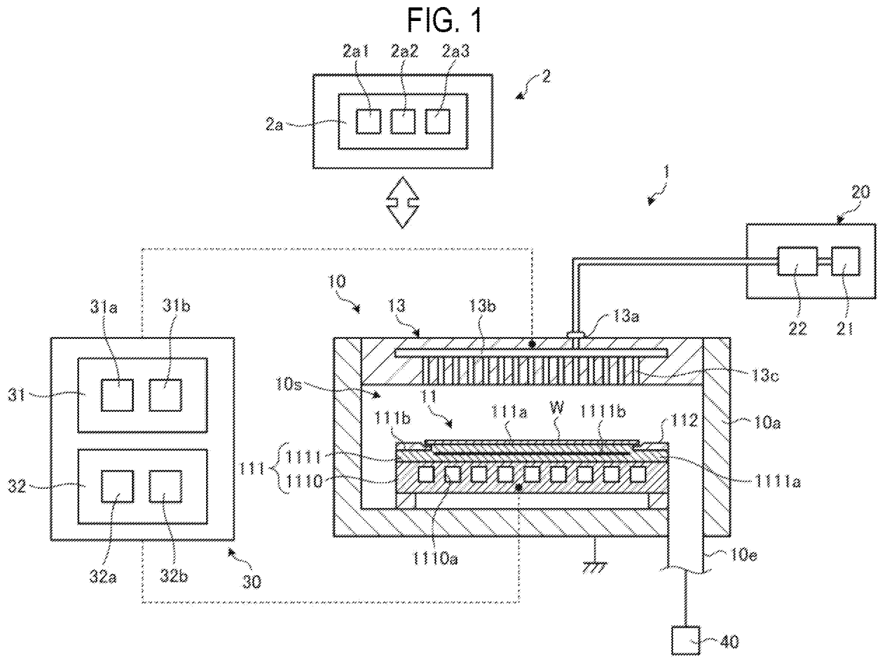

Hereinafter, a configuration example of a plasma processing system will be described. FIG. 1 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body portion 111 has a central region 111a for supporting the substrate W and an annular region 111b for supporting the ring assembly 112. The wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power supply 31 and/or a direct current (DC) power supply 32 to be described later may be disposed in the ceramic member 1111a. In this case, the at least one RF/DC electrode functions as the lower electrode. In a case where the bias RF signal and/or the DC signal to be described later are supplied to the at least one RF/DC electrode, the RF/DC electrode is also referred to as a bias electrode. The conductive member of the base 1110 and the at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one selected from the group of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between the rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or more side gas injectors (SGI) that are attached to one or more openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse the flow rates of the at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode may generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one selected from the group of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate a first DC signal. The generated first bias DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one selected from the group of the first and second DC signals may be pulsed. In this case, a sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator constitute a voltage pulse generator. In a case where the second DC generator 32b and the waveform generator constitute the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, a part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

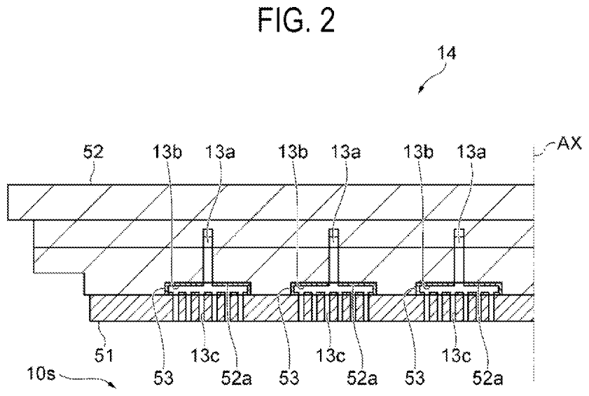

Hereinafter, a configuration of an upper electrode of a plasma processing apparatus according to one exemplary embodiment will be described with reference to FIG. 2. FIG. 2 is a cross-sectional view of an upper electrode according to one exemplary embodiment. In the plasma processing apparatus 1, an upper electrode 14 shown in FIG. 2 forms the shower head 13. The upper electrode 14 shown in FIG. 2 may be used as an upper electrode of the capacitively-coupled plasma processing apparatus 1.

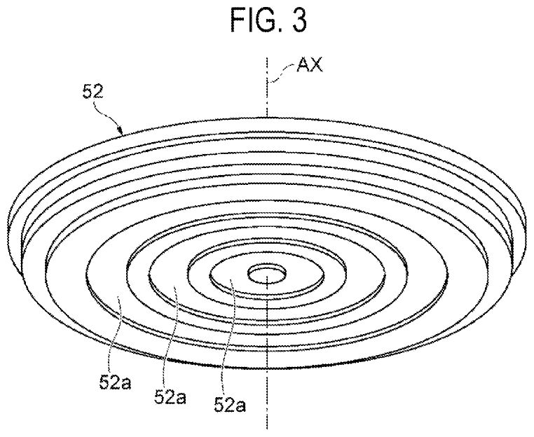

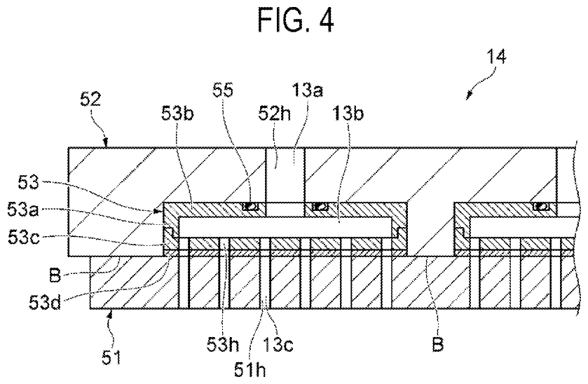

As shown in FIG. 2, the upper electrode 14 includes a first member 51, a second member 52, and at least one third member 53. FIGS. 3 and 4 will be referred to in addition to FIG. 2. FIG. 3 is a perspective view of a second member according to one exemplary embodiment. FIG. 4 is a cross-sectional view illustrating a part of the upper electrode according to one exemplary embodiment.

The first member 51 may be a top plate that defines a space inside the plasma processing chamber 10 (the plasma processing space 10s) from above. The first member 51 may have an axis AX as a central axis thereof, or may have a substantially disc shape. The axis AX extends in a vertical direction. The first member 51 is formed of a conductor. The first member 51 may be formed of, for example, a silicon-containing material such as silicon or silicon carbide. As shown in FIG. 4, the first member 51 provides a plurality of first gas holes 51h. The plurality of first gas holes 51h penetrates the first member 51 in a plate thickness direction thereof. The plurality of first gas holes 51h may constitute a plurality of gas introduction ports 13c.

As shown in FIGS. 2 and 4, the second member 52 is provided on or above the first member 51. The second member 52 is formed of a conductor. The second member 52 may be formed of a metal such as aluminum. As shown in FIG. 3, the second member 52 may have the axis AX as a central axis thereof, or may have a substantially disc shape. The second member 52 provides one or more second gas holes 52h. Each of the one or more second gas holes 52h constitutes the gas supply port 13a. The second member 52 may be capable of being cooled. The second member 52 may provide a flow path through which the refrigerant flows therein.

At least one third member 53 is formed of a dielectric. The at least one third member 53 is formed of, for example, ceramics such as alumina and aluminum nitride, resin such as polytetrafluoroethylene (PTFE) and polyimide, quartz, or the like. In one embodiment, at least one third member 53 may be a porous body.

The at least one third member 53 is provided between the first member 51 and the second member 52. The at least one third member 53 defines at least one gas diffusion chamber 13b. The plurality of first gas holes 51h and the one or more second gas holes 52h are connected to the at least one gas diffusion chamber 13b.

In one embodiment, the upper electrode 14 may include a plurality of third members 53. The number of the plurality of third members 53 may be three as shown in FIG. 2. The plurality of third members 53 may define the plurality of gas diffusion chambers 13b, respectively, as at least one gas diffusion chamber 13b. The plurality of first gas holes 51h (that is, the plurality of gas introduction ports 13c) and the corresponding one or more second gas holes 52h (that is, the gas supply ports 13a) may be connected to each of the plurality of gas diffusion chambers 13b.

As shown in FIG. 3, for example, the second member 52 may define a plurality of grooves 52a that are opened downward. The number of grooves 52a provided by the second member 52 is, for example, three. Each of the plurality of grooves 52a extends in a peripheral direction around the axis AX, and has an annular shape. The plurality of grooves 52a is provided concentrically with respect to the axis AX. That is, the plurality of grooves 52a is disposed along a radial direction. The radial direction and the peripheral direction are directions with the axis AX as a reference. As shown in FIG. 2, the plurality of third members 53 may be provided in the plurality of grooves 52a, respectively. In this case, each of the plurality of gas diffusion chambers 13b may be formed in the corresponding groove 52a.

Hereinafter, one gas diffusion chamber 13b among the plurality of gas diffusion chambers 13b of the upper electrode 14 and one third member 53 that defines the one gas diffusion chamber 13b will be described. As shown in FIG. 4, the gas diffusion chamber 13b is connected to the plurality of first gas holes 51h and one or more second gas holes 52h. As an example, one second gas hole 52h is connected to the gas diffusion chamber 13b.

In one embodiment, the upper electrode 14 may further include a sealing member 55 (second sealing member). The sealing member 55 is held between the second member 52 and the third member 53. The sealing member 55 may be an O-ring or a gasket. The upper electrode 14 may include a plurality of sealing members 55 corresponding to the plurality of third members 53, respectively.

In one embodiment, the third member 53 may include a sidewall 53a, a ceiling portion 53b, and a bottom portion 53c. The sidewall 53a extends in the peripheral direction to surround the gas diffusion chamber 13b. The ceiling portion 53b extends on the gas diffusion chamber 13b. The bottom portion 53c is disposed below the gas diffusion chamber 13b. The third member 53 may be a single member or may be formed by a plurality of members. For example, the sidewall 53a, the ceiling portion 53b, and the bottom portion 53c may be separate members. Alternatively, as shown in FIG. 4, in the third member 53, the ceiling portion 53b may be a member separate from the sidewall 53a and the bottom portion 53c, and the sidewall 53a and the bottom portion 53c may be a single member and integrated with each other.

In one embodiment, the ceiling portion 53b is disposed to face an open end of each of the plurality of first gas holes 51h on the side of the gas diffusion chamber 13b. The ceiling portion 53b may provide a through-hole communicating with the second gas hole 52h. The through-hole of the third member 53 may be aligned with the second gas hole 52h. The sealing member 55 is, for example, an O-ring. In one embodiment, the sealing member 55 may be held between the ceiling portion 53b and the second member 52. As an example, the sealing member 55 is disposed in a groove formed in the ceiling portion 53b to surround the second gas hole 52h. In this case, the sealing member 55 is in contact with the bottom surface of the groove 52a. The ceiling portion 53b may have a thickness of 3 mm or less.

In one embodiment, the bottom portion 53c may provide a plurality of third gas holes 53h. The plurality of third gas holes 53h penetrates the bottom portion 53c. The plurality of third gas holes 53h respectively connects the plurality of first gas holes 51h to the gas diffusion chamber 13b. The plurality of third gas holes 53h is aligned with the plurality of first gas holes 51h, respectively. The centerline of each of the plurality of third gas holes 53h may be aligned with the centerline of each of the plurality of first gas holes 51h.

In one embodiment, the third member 53 may have the contact portion 53d that is in contact with the first member 51. The contact portion 53d is a part of the bottom portion 53c and is a part which is in contact with an upper surface of the first member 51. The contact portion 53d is formed of a member having a friction coefficient lower than a friction coefficient of a portion other than the contact portion 53d of the third member 53, that is, the low friction member. The low friction member is, for example, polytetrafluoroethylene (PTFE).

In one embodiment, the third member 53 may separate the boundary B between the first member 51 and the second member 52 from the gas diffusion chamber 13b. For example, the bottom portion 53c may separate the boundary B from the gas diffusion chamber 13b. In this case, the bottom portion 53c extends along the upper surface of the first member 51 and two side surfaces of the second member 52 that defines the groove 52a to fill two corners (a corner on the inner diameter side and a corner on the outer diameter side) formed by the upper surface of the first member 51 and the two side surfaces of the second member 52.

As described above, in the upper electrode 14, the gas diffusion chamber 13b is defined by the third member 53 formed of a dielectric. Therefore, even when the electrons or positive ions enter the gas diffusion chamber 13b from each of the plurality of first gas holes 51h and collide with the third member 53 that defines the gas diffusion chamber 13b, the amount of secondary electrons emitted from the third member 53 is small. As a result, an abnormal discharge in the upper electrode 14 is suppressed.

Further, in the upper electrode 14, the sealing member 55 suppresses the formation of the flow of the processing gas toward a gap between the second member 52 and the third member 53. Accordingly, the flow of the processing gas formed in the gas diffusion chamber 13b is stabilized by the sealing member 55.

Further, the sealing member 55 is held between the second member 52 and the third member 53, thereby exerting a reaction force with respect to the third member 53. The relative position of the third member 53 with respect to the first member 51 is fixed by the reaction force. Therefore, the friction between the third member 53 and the first member 51 is suppressed. As a result, the generation of particles due to the friction between the third member 53 and the first member 51 is suppressed.

Further, since the open end of each of the plurality of first gas holes 51h faces the ceiling portion 53b, most of the electrons or positive ions entering the gas diffusion chamber 13b from each of the plurality of first gas holes 51h tend to collide with the ceiling portion 53b. The secondary electrons are less likely to be emitted from the ceiling portion. Therefore, the abnormal discharge in the upper electrode 14 is further suppressed.

Further, the electrons or positive ions entering the plurality of first gas holes 51h may collide with the wall surface that defines the plurality of third gas holes 53h before reaching the gas diffusion chamber 13b. The wall surface that defines the plurality of third gas holes 53h is less likely to emit the secondary electrons. Therefore, the abnormal discharge in the upper electrode 14 is further suppressed.

Further, in the upper electrode 14, the boundary B where an abnormal discharge is easily generated is blocked by the third member 53. Therefore, the abnormal discharge in the upper electrode 14 is further suppressed.

Further, in the upper electrode 14, the frictional resistance between the first member 51 and the third member 53 is reduced by the contact portion 53d. As a result, the generation of particles due to the friction between the first member 51 and the third member 53 is suppressed.

Hereinafter, upper electrodes according to various different exemplary embodiments will be described. Hereinafter, differences from the upper electrode 14 related to the upper electrode according to various different exemplary embodiments will be described, and duplicate descriptions thereof will be omitted.

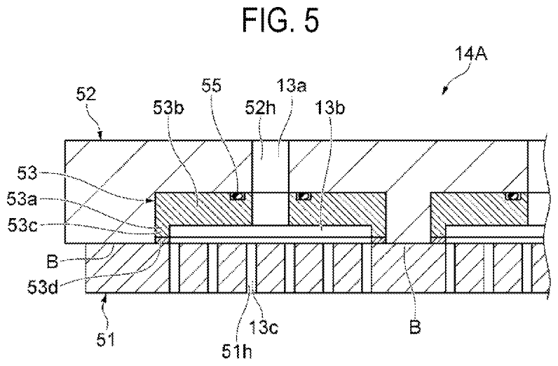

First, FIG. 5 will be referred to. FIG. 5 is a cross-sectional view illustrating a part of an upper electrode according to another exemplary embodiment. Hereinafter, one gas diffusion chamber 13b among the plurality of gas diffusion chambers 13b of an upper electrode 14A shown in FIG. 5 and the third member 53 that defines the one gas diffusion chamber 13b will be described.

As shown in FIG. 5, the bottom portion 53c may not provide the third gas hole 53h. In this case, the third member 53 defines the gas diffusion chamber 13b together with the first member 51, and the bottom portion 53c surrounds the gas diffusion chamber 13b. In this case, the plurality of first gas holes 51h is directly connected to the gas diffusion chamber 13b. In this case, the ceiling portion 53b has a thickness of, for example, 5 mm.

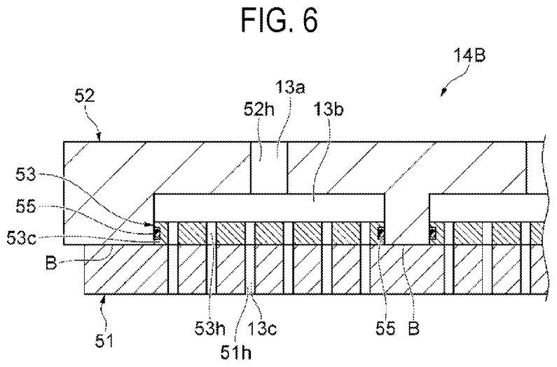

Hereafter, FIG. 6 will be referred to. FIG. 6 is a cross-sectional view illustrating a part of an upper electrode according to yet another exemplary embodiment. Hereinafter, one gas diffusion chamber 13b among the plurality of gas diffusion chambers 13b of an upper electrode 14B shown in FIG. 6 and the third member 53 that defines the one gas diffusion chamber 13b will be described.

As shown in FIG. 6, the third member 53 may not include the sidewall 53a and the ceiling portion 53b. In this case, the third member 53 may include the bottom portion 53c providing the plurality of third gas holes 53h. In this case, the third member 53 defines the gas diffusion chamber 13b together with the second member 52. The third member 53 may not include the contact portion formed of the low friction member.

As shown in FIG. 6, the upper electrode 14B may include two sealing members 55 corresponding to one third member 53. Each of the two sealing members 55 has an annular shape around the axis AX. One of the two sealing members 55 is held between one of the two sidewall surfaces (sidewall surface on the inner diameter side) of the second member 52 that defines the groove 52a and one sidewall surface of the bottom portion 53c. The other of the two sealing members 55 is held between the other of the two sidewall surfaces (sidewall surface on the outer diameter side) of the second member 52 that defines the groove 52a and the other sidewall surface of the bottom portion 53c.

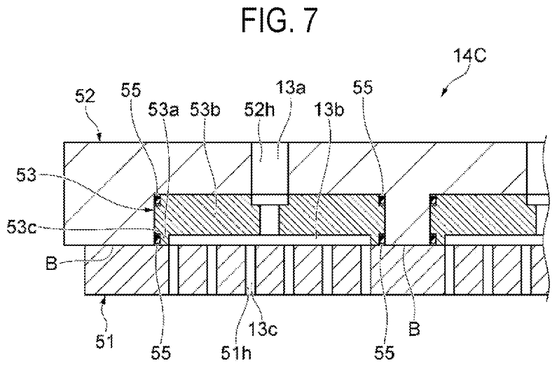

Hereafter, FIG. 7 will be referred to. FIG. 7 is a cross-sectional view illustrating a part of an upper electrode according to still another exemplary embodiment. Hereinafter, one gas diffusion chamber 13b among the plurality of gas diffusion chambers 13b of an upper electrode 14C shown in FIG. 7 and the third member 53 that defines the one gas diffusion chamber 13b will be described.

In one embodiment, as shown in FIG. 7, the boundary B between the first member 51 and the second member 52 may be separated from the gas diffusion chamber 13b by the sealing member 55. As shown in FIG. 7, the upper electrode 14C may include a plurality of sealing members 55 corresponding to the one third member 53. In an example, as shown in FIG. 7, the upper electrode 14C includes four sealing members 55. The four sealing members 55 have annular shapes around the axis AX. Two of the four sealing members 55 are held between one of the two sidewall surfaces (sidewall surface on the inner diameter side) of the second member 52 that defines the groove 52a and the third member 53. The other two of the four sealing members 55 are held between the other of the two sidewall surfaces (the sidewall surface on the outer diameter side) of the second member 52 that defines the groove 52a and the third member 53.

The two sealing members 55 disposed in an upper portion among the four sealing members 55 may be disposed at the two corners on the upper end side (a corner on the inner diameter side and a corner on the outer diameter side) of the groove 52a, respectively. The two sealing members 55 disposed in the upper portion among the four sealing members 55 may be in contact with the two sidewalls of the second member 52 that defines the groove 52a, and the ceiling portion 53b. Further, the other two sealing members 55 disposed in a lower portion among the four sealing members 55 may be disposed at the two corners (a corner on the inner diameter side and a corner on the outer diameter side) formed by the upper surface of the first member 51 and the two side surfaces of the second member 52 that defines the groove 52a, respectively. Each of the two sealing members 55 disposed in the lower portion among the four sealing members 55 may be in contact with the sidewall of the third member 53 that defines the groove 52a and the upper surface of the first member 51. In this case, the ceiling portion 53b has a thickness of, for example, 5 mm or more.

Further, in the upper electrode 14C, the boundary B where an abnormal discharge is easily generated is separated from the gas diffusion chamber 13b by the sealing member 55. Therefore, the abnormal discharge in the upper electrode 14C is further suppressed.

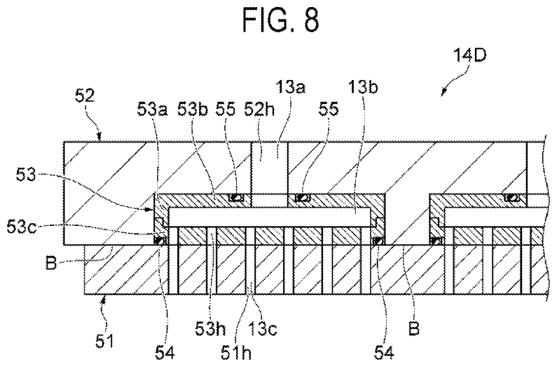

Hereinafter, FIG. 8 will be referred to. FIG. 8 is a cross-sectional view illustrating a part of an upper electrode according to yet another exemplary embodiment. Hereinafter, one gas diffusion chamber 13b among the plurality of gas diffusion chambers 13b of an upper electrode 14D shown in FIG. 8 and the third member 53 that defines the one gas diffusion chamber 13b will be described.

As shown in FIG. 8, the upper electrode 14D may further include a sealing member 54 (first sealing member). The sealing member 54 may be an O-ring or a gasket. The upper electrode 14D may include a plurality of sealing members 54 corresponding to the plurality of third members 53, respectively. Hereinafter, at least one sealing member 54 corresponding to one third member 53 will be described. The upper electrode 14D may include two sealing members 54 corresponding to the third member 53. Each sealing member 54 is held between the first member 51 and the third member 53. More specifically, each sealing member 54 may be held between the first member 51 and the bottom portion 53c.

Each sealing member 54 is, for example, an O-ring. Each of the two sealing members 54 may be disposed at two corners (a corner on the inner diameter side and a corner on the outer diameter side) formed by the upper surface of the first member 51 and two side surfaces of the second member 52 that defines the groove 52a. Each of the two sealing members 54 may be held between the bottom portion 53c of the third member 53 and the upper surface of the first member 51. As shown in FIG. 8, each of the two sealing members 54 may separate the boundary B between the first member 51 and the second member 52 from the gas diffusion chamber 13b. Further, the sealing member 54 may separate the boundary B between the first member 51 and the second member 52 from the third gas hole 53h. In another embodiment, the sealing member 55 may separate the boundary B between the first member 51 and the second member 52 from the third gas hole 53h.

In the upper electrode 14D, the sealing member 54 suppresses the formation of the flow of a processing gas toward a gap between the first member 51 and the third member 53. Accordingly, the flow of the processing gas formed in the gas diffusion chamber 13b is stabilized by the sealing member 54.

Further, in the upper electrode 14D, particles that may be generated by the friction between the third member 53 and the first member 51 are suppressed from entering the plurality of first gas holes 51h.

Further, in the upper electrode 14D, the boundary B where an abnormal discharge is easily generated is separated from the gas diffusion chamber 13b by the sealing member 54. Therefore, the abnormal discharge in the upper electrode 14D is further suppressed.

Further, in the upper electrode 14D, particles that may be generated by the friction between the third member 53 and the first member 51 are suppressed from entering the plurality of third gas holes 53h.

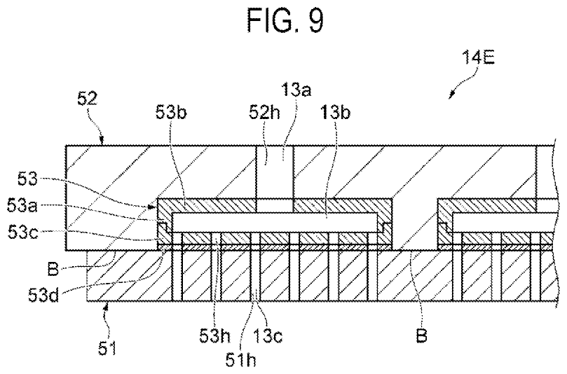

Hereinafter, FIG. 9 will be referred to. FIG. 9 is a cross-sectional view illustrating a part of an upper electrode according to still another exemplary embodiment. Hereinafter, one gas diffusion chamber 13b among the plurality of gas diffusion chambers 13b of an upper electrode 14E shown in FIG. 9 and the third member 53 that defines the one gas diffusion chamber 13b will be described. As shown in FIG. 9, the upper electrode 14E may not include the sealing member 54 and the sealing member 55. In another embodiment, the upper electrode may include at least one selected from the group of the sealing member 54 and the sealing member 55.

While various exemplary embodiments have been described above, various additions, omissions, substitutions and changes may be made without being limited to the exemplary embodiments described above. Indeed, the embodiments described herein may be embodied in a variety of other forms.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

According to one exemplary embodiment, an abnormal discharge in an upper electrode is suppressed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An upper electrode forming a shower head in a capacitively-coupled plasma processing apparatus, the upper electrode comprising:
a first member that is formed of a conductor, the first member providing a plurality of first gas holes that penetrate the first member;
a second member that is formed of a conductor and provided on the first member, the second member providing one or more second gas holes; and
a third member that is formed of a dielectric and provided between the first member and the second member, the third member defining a gas diffusion chamber in which the plurality of first gas holes and the one or more second gas holes are connected.

2. The upper electrode of claim 1, further comprising:
at least one selected from the group of a first sealing member held between the first member and the third member and a second sealing member held between the second member and the third member.

3. The upper electrode of claim 2, wherein the third member includes a sidewall extending in a peripheral direction to surround the gas diffusion chamber, and a ceiling portion extending on the gas diffusion chamber, and
wherein the second sealing member is held between the sidewall and the second member or between the ceiling portion and the second member.

4. The upper electrode of claim 3, wherein the ceiling portion is disposed to face an open end of each of the plurality of first gas holes on a side of the gas diffusion chamber.

5. The upper electrode of claim 4, wherein the third member includes a bottom portion disposed below the gas diffusion chamber.

6. The upper electrode of claim 5, wherein the bottom portion provides a plurality of third gas holes aligned with the plurality of first gas holes, respectively.

7. The upper electrode of claim 6, wherein the second sealing member is held between the second member and the bottom portion.

8. The upper electrode of claim 7, wherein the first sealing member is held between the first member and the bottom portion.

9. The upper electrode of claim 8, wherein at least one selected from the group of the first sealing member and the second sealing member separates a boundary between the first member and the second member from the gas diffusion chamber.

10. The upper electrode of claim 9, wherein the third member separates a boundary between the first member and the second member from the gas diffusion chamber.

11. The upper electrode of claim 10, wherein the third member has a contact portion that is in contact with the first member, and
wherein the contact portion is formed of a low friction member having a lower friction coefficient than that of a portion other than the contact portion of the third member.

12. The upper electrode of claim 11, wherein the dielectric is a porous body.

13. The upper electrode of claim 6, wherein at least one selected from the group of the first sealing member and the second sealing member separates a boundary between the first member and the second member from the plurality of third gas holes.

14. The upper electrode of claim 2, wherein at least one selected from the group of the first sealing member and the second sealing member is an O-ring or a gasket.

15. The upper electrode of claim 1, wherein the third member separates a boundary between the first member and the second member from the gas diffusion chamber.

16. The upper electrode of claim 1, wherein the third member has a contact portion that is in contact with the first member, and
wherein the contact portion is formed of a low friction member having a lower friction coefficient than that of a portion other than the contact portion of the third member.

17. The upper electrode of claim 1, wherein the dielectric is a porous body.

18. A plasma processing apparatus comprising:
a plasma processing chamber that provides a processing space inside the plasma processing chamber;
a substrate support that is provided in the plasma processing chamber; and
the upper electrode of claim 1, the upper electrode being provided above the substrate support.
